(19) United States
(12) Patent Application Publication
(10) Pub. No.: US 2023/0307895 A1
(43) Pub. Date: Sep. 28, 2023

(54) ELECTRIC DEVICE HAVING MULTIPLE DISPLAYS, AND CONTROL METHOD THEREFOR

(71) Applicant: ROOTECH INC., Suwon-si, Gyeonggi-do (KR)

(72) Inventors: Changyong JEONG, Suwon-si, Gyeonggi-do (KR); Youngbok BYUN, Yongin-si Gyeonggi-do (KR)

(73) Assignee: ROOTECH INC., Suwon-si, Gyeonggi-do (KR)

(21) Appl. No.: 17/927,351

(22) PCT Filed: May 7, 2021
(86) PCT No.: PCT/KR2021/005698

§ 371 Date: Nov. 22, 2022

(30) Foreign Application Priority Data
May 26, 2020 (KR) 10-2020-0063132

(51) Int. Cl. H02B 1/03; H02B 1/30; H02H 3/04

(52) U.S. Cl. CPC H02B 1/03; H02B 1/306; H02H 3/04; G01R 19/2513

(57) ABSTRACT

An electric device having multiple displays, and a control method therefor are proposed. The electric device is mounted on a supporting body, and includes a first display (10) and a second display (20), which are configured in a same housing (30) and are facing a front, wherein one of the first display (10) and the second display (20) provides a rectangular horizontal screen and displays information about a meter function, and the other of the first display (10) and the second display (20) provides a rectangular vertical screen and displays information about a relay function.

### TECHNICAL FIELD

The present disclosure relates to an electric device having two or more displays and, more particularly, to a relay having two or more displays and also having a meter function.

### BACKGROUND ART

A distributing board is a main device of a power system, and may be configured to include: a circuit breaker that forms a supply and blocking path of power; a relay as a device for controlling such a circuit breaker; and a meter as a device for measuring the power. Although voltage and current specifications of the said device change depending on ultra-high voltage, high voltage, and low voltage, fundamental configurations are almost the same. Such distributing boards serve as facilities for supplying power in various places.

The relay is a control device for protecting power facilities in cooperation with the circuit breaker in an event of an accident in the power system. Recently, by combining digital technology and communication technology, the relay has become more intelligent and is developing into a form that enables various analysis and accident response. As a change occurs from an analog relay to a digital relay, a relay is being developed into a complex type in which a meter function is integrated and performed in the same device as the relay while the original function of the relay is retained. Recently, in order to provide a lot of information and ease of analysis on a display screen, there are increasing cases where an LCD rather than a simple 7-segment screen is applied. FIG. 1A is a view illustrating an example of a configuration of a distributing board, and FIG. 1B is a view illustrating an example of a commercial relay to which an LCD display device is applied.

Meanwhile, in almost all relays, a relay uses a single LCD to configure a screen, and information (i.e., measurement factors) related to a function of a meter and information related to the relay for performing a protection function are simultaneously displayed in the single screen. Due to such a configuration, complexity increases, and thus visibility is reduced and user convenience is deteriorated.

Recently, with the advent of a relay to which a TFT LCD is applied, displaying of various graphics and colors is enabled, and models for increasing visibility are emerging, but there is a limit to improving the convenience and visibility by using the single TFT LCD. In particular, a device configured as a complex type performs both the meter function and the relay function at the same time, but has weaknesses in the convenience and visibility because the functions having different characteristics are displayed on the single screen.

As such, the complex type relay having the single screen has difficulties in use due to complexity thereof. In order to solve such problems, the inventor of the present disclosure has devised a method of displaying the information related to the meter function and the relay function by using two or more displays, for example, two displays, and a method of increasing the convenience of analysis and operation by using both screens at the same time. Furthermore, in applying two or more displays, the inventor of the present disclosure desires to propose a solution for solving newly emerging problems and improving efficiency and others.

Although the problems and solutions of the related art have been described above, recognition of these problems and solutions is not obvious to those skilled in the art of the present disclosure.

### DISCLOSURE

### Technical Problem

An objective of the present disclosure is to provide an electric device and a control method thereof, wherein, in the electric device having two or more functions, information on such functions may be realized with good visibility and convenience.

In addition, another objective of the present disclosure is to provide an electric device and a control method thereof, wherein, efficiency and the like are provided in configuring two or more displays in the electric device having two or more functions.

### Technical Solution

According to one aspect of the present disclosure, there is provided an electric device mounted on a supporting body, the electric device including: a first display 10 and a second display 20, which are configured in a same housing 30 and are facing a front, wherein one of the first display 10 and the second display 20 provides a rectangular horizontal screen and displays information about a meter function, and the other of the first display 10 and the second display 20 provides a rectangular vertical screen and displays information about a relay function.

According to another aspect of the present disclosure, there is provided an electric device mounted on a supporting body, the electric device including: a first display 10 and a second display 20, which are configured in a same housing 30 and are facing a front, wherein the first display 10 and the second display 20 are both rectangular and a long side direction of the first display 10 and a long side direction of the second display 20 are orthogonal to each other, so that regardless of whether the electric device is mounted horizontally or vertically on the supporting body, one of the first display 10 and the second display 20 always provides a horizontal screen and the other of the first display 10 and the second display 20 always provides a vertical screen.

According to one aspect of the present disclosure, there is provided a control method of an electric device mounted on a supporting body and provided with a first display 10 and a second display 20, which are configured in a same housing 30 and are facing a front, the control method including: determining a mounting direction in which the electric device is mounted on the supporting body, wherein the first display and the second display 20 are both rectangular, and a long side direction of the first display 10 and a long side direction of the second display are orthogonal to each other; and determining information displayed on the first display 10 and the second display 20 to be different depending on the determined mounting direction.

### Advantageous Effects

In the electric device and the control method thereof according to one aspect of the present disclosure, there is a strong point that in the electric device having two or more functions, the information on each function may be displayed with good visibility and convenience.

In addition, in the electric device and control method thereof according to one aspect of the present disclosure, since both of the horizontal screen and the vertical screen may be provided regardless of the mounting direction, there is an effect that an appropriate display (i.e., the meter function display) by the horizontal screen and an appropriate display (i.e., the relay function display) by the vertical screen may always be provided at the same time.

In addition, in the electric device and control method thereof according to one aspect of the present disclosure, regardless of the mounting direction of the electric device (i.e., the relay), the screens (i.e., the horizontal screen and vertical screen) of the same format may always be provided, so there is another strong point that regardless of whether a condition of an installation target (i.e., a box, a cabinet, a drawer, a panel, or a rack) is suitable for a horizontal type electric device or a vertical type electric device, flexible response is enabled, design freedom are provided, and further, the same products are not required to be designed, manufactured, and distributed separately in the horizontal type and vertical type.

In addition, in the electric device and control method thereof according to one aspect of the present disclosure, respective character strings displayed on input buttons are inclined toward a space between two displays, whereby there is an effect that recognition of the respective character strings displayed on the input buttons are made easier even in a condition where the mounting direction of the electric device is variable.

### DESCRIPTION OF DRAWINGS

FIG. 1A is a view illustrating an example of a configuration of a distributing board, and FIG. 1B is a view illustrating an example of a commercial relay to which an LCD display device is applied.

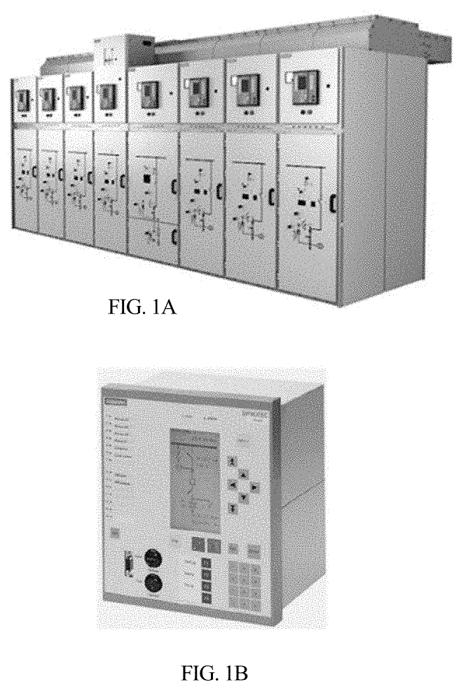

FIGS. 2A-2D illustrate examples of respective relays to which two displays are applied. FIGS. 2A and 2B are views illustrating respective relays to which two horizontal displays are applied. FIGS. 2C and 2D are views illustrating respective relays to which two vertical displays are applied.

FIGS. 3A and 3B are views illustrating the appearance of an electric device according to an exemplary embodiment of the present disclosure. FIG. 3A illustrates an example in which the electric device is mounted horizontally, and FIG. 3B illustrates an example in which the electric device is mounted vertically.

FIG. 4 is a schematical view illustrating electrical functional blocks of the electric device according to the exemplary embodiment of the present disclosure.

### BEST MODE

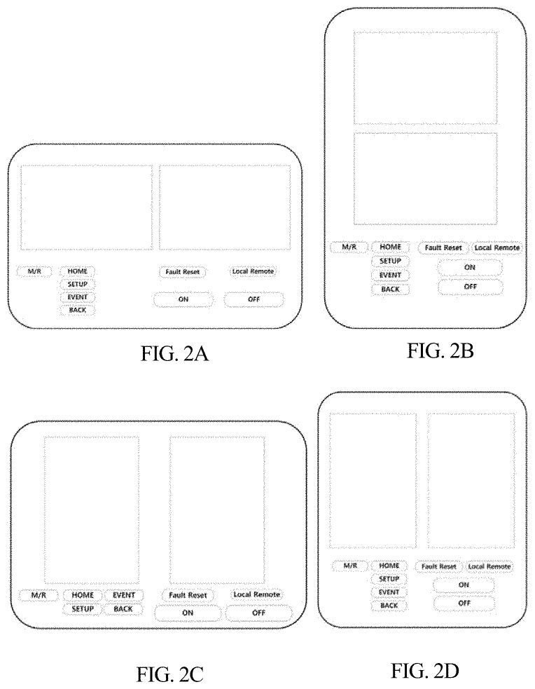

FIGS. 2A-2D illustrate examples of respective relays to which two displays are applied. FIGS. 2A and 2B are views illustrating respective relays to which two horizontal displays are applied. FIGS. 2C and 2D are views illustrating respective relays to which two vertical displays are applied.

The examples of FIGS. 2A-2D illustrate intermediate embodiments of disclosure devised during a process leading to the present disclosure, and have independent screens for a meter function and a relay function. The content displayed on each screen is configured and displayed independently by dividing a meter and a relay by function. The content to be mainly displayed on each screen is determined, and accordingly, factors having the characteristics of the meter and relay may be displayed efficiently and convenience may be increased.

When a user malfunctions the relay, this incident may lead to a critical accident such as a power outage. Since the relay has independent screens, the user may safely manage the device. In addition, in a general operation condition, checking of measurement values on a meter screen is the main operation and manipulation and there is almost no manipulation related to the relay, so not only reliability may be secured, but also user's psychological stability may be provided.

In addition, since each of the meter and the relay has an independent screen, operation is performed through the meter screen except in an event of an accident, so that the reliability may be secured and user's malfunction may also be maximally reduced, whereby when the accident is analyzed, effective analysis and device management may be conducted by using two screens.

However, a relay may be manufactured in various forms depending on internal and external configurations when the relay is mounted on a distributing board, etc. In particular, depending on the distributing board, a horizontal type relay having a longer horizontal length may be suitable, or a vertical type relay having a longer vertical length may be suitable. Due to such a condition, a manufacturer has a burden of manufacturing the horizontal type relay and the vertical type relay, separately, depending on the distributing board.

When a shape of a relay is square, such a configuration may be satisfied, but products that are not square in structure are common, so in a case of manufacturing distributing boards that are limited to horizontal type or vertical type products, a horizontal or vertical type distributing board may not be applied as desired.

In general, a shape of a display used in a product is rectangular, and when the display are configured with two screens, a structure of the display becomes one of the structures as shown in FIGS. 2A-2D. However, in such a structure, a horizontally long relay and a vertically long relay should be manufactured and supplied according to the shape of a distributing board, and only when there are independent models for each need, a smooth response may be enabled.

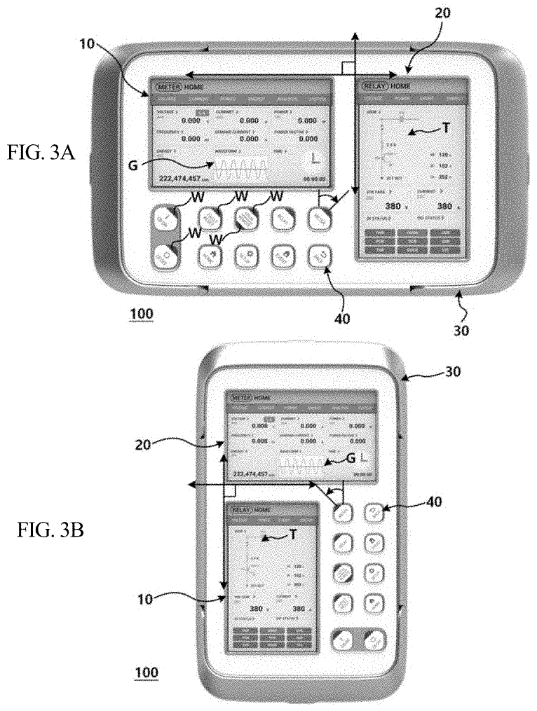

FIGS. 3A and 3B are views illustrating the appearance of the electric device according to the exemplary embodiment of the present disclosure. FIG. 3A illustrates an example in which the electric device is mounted horizontally, and FIG. 3B illustrates an example in which the electric device is mounted vertically.

FIGS. 3A and 3B illustrate that the same electric device 100 is mounted on a supporting body (not shown), such as a distributing board, by changing, that is, by rotating, a mounting direction according to a configuration condition of the distributing board. The supporting body may be or be a part of a box, a cabinet, a drawer, a panel, a rack, or the like. The electric device 100 according to the exemplary embodiment of the present disclosure may be a relay (hereinafter, for convenience of description, the “electric device” may be referred to as a “relay”, and the relay may additionally have the function of a meter). Various components are configured in the housing 30, and in particular, a first display 10, a second display 20, and a plurality of buttons 40, which are facing the front, are provided in the housing 30.

The first display 10 and the second display 20 are flat panel displays, such as LCDs or OLEDs, and are preferably provided with a touch screen function. Both of the first display 10 and the second display 20 are configured in the same electric device, that is, the same housing 30. Both of the first display 10 and the second display 20 are rectangular, and as shown in the drawing, the long side directions of the first display 10 and the long side direction of the second display 20 are orthogonal to each other. Here, the term “orthogonal” does not mean exactly 90 degrees, and means that, depending on a mounting condition of the relay, the displays are configured in the housing in such a way that when one display is in the horizontal direction, the other display is in the vertical direction.

In the electric device 100 mounted on the supporting body such as the distributing board, one of the first display 10 and the second display 20 provides a rectangular horizontal screen and displays information about the meter function in normal times, and the other of the first display 10 and the second display 20 provides a rectangular vertical screen and displays information about the relay function in normal times.

Regardless of whether the electric device 100 is mounted horizontally or vertically on the supporting body, one of the first display 10 and the second display 20 always provides the horizontal screen and the other of the first display 10 and the second display 20 always provides the vertical screen. When a relay shown in FIG. 3A is rotated counterclockwise by 90 degrees, the relay becomes a relay shown in FIG. 3B (i.e., the content displayed on the displays are switched with each other).

For example, when the electric device 100 is mounted on the supporting body in the horizontal direction, the first display 10 provides the horizontal screen and the second display 20 provides the vertical screen, and due to changing of the mounting direction, when the electric device 100 is mounted on the supporting body in the vertical direction, the first display 10 provides the vertical screen and the second display 20 provides the horizontal screen.

The information displayed on the first display 10 when the electric device is mounted on the supporting body in the horizontal direction is displayed on the second display 20 when the electric device is changed to be mounted on the supporting body in the vertical direction. In addition, the information displayed on the second display 20 when the electric device is mounted on the supporting body in the horizontal direction is displayed on the first display 10 when the electric device is changed to be mounted on the supporting body in the vertical direction.

Regardless of whether the electric device is mounted horizontally or vertically on the supporting body, in normal times, the horizontal screen fundamentally displays the information about the meter function, and the vertical screen fundamentally displays the information about the relay function. The information about the meter function includes analysis of properties such as voltage, current, power, energy, frequency, power factors, and harmonic waves, and in particular, includes waveform information G about some of the said properties. In addition, the information about the relay function includes a distribution diagram T and information, which may be displayed on such a distribution diagram T, such as state information of a circuit breaker and operation state information of the relay.

According to the exemplary embodiment of the present disclosure, even when the relay is rotated according to the configuration of the distributing board, since displaying content on the horizontal screen is maintained for specific information (e.g., information related to the meter function) and displaying content on the vertical screen is maintained for different specific information (e.g., information related to the relay function) in accordance with the rotational change, there is an effect that, depending on the manufacture and on-site conditions, the same product may be rotated 90 degrees so as to configure a suitable product, and may be applicable according to any distributing board structure that is required.

In addition, the housing 30 is configured with a plurality of input buttons 40 facing the front. Respective character strings displayed on the input buttons 40 are inclined toward a space between the first display 10 and the second display 20. Assuming that the respective character strings displayed on the input buttons 40 are not inclined and are facing, for example, the first display 10, recognition of the respective character strings are easy in a condition where the electric device is mounted as shown in FIG. 3A, but in a case where the electric device is mounted in a state of being rotated 90 degrees as shown in FIG. 3B, the user's visual recognition becomes inconvenient. When the input buttons are arranged and displayed in parallel in accordance with the horizontal type, in a case where the input buttons are changed to become the vertical type, the respective characters are displayed in a 90 degree-rotated state, so visual recognition becomes difficult, and vice versa. That is, conversely, there is a similar difficulty in visual recognition as well. In addition, there are respective LED windows for display according to operation keys, and in such a structure, as in the case of the operation keys, there is a difficulty in arranging the respective LED windows.

According to the exemplary embodiment of the present disclosure, the respective character strings displayed on the input buttons 40 are made to be inclined toward the space between the first display 10 and the second display 20, so that there is an effect that the recognition of the respective character strings displayed on the input buttons 40 becomes easier even in a condition where the mounting direction of the electric device is variable. According to the present disclosure, the respective characters displayed on the input buttons are diagonally arranged so that a product is configured to be able to respond to any case of the horizontal type or vertical type when the product is mounted on a distributing board.

In addition, respective LED light-transmitting windows for displaying operation states of the input buttons are also arranged at respective corners of the input buttons, so as to respond to any case of the horizontal type or vertical type as in the case of the respective characters of the input buttons, thereby improving visibility.

In some or all of the plurality of input buttons, on respective corner portions facing the space between the first display 10 and the second display 20, or on respective corner portions opposite to the above corner portions, the respective light-transmitting windows W for LED lamps are provided, and the LED lamps are provided inside the respective light-transmitting windows W. An LED display light-transmitting window configured on a corner is used to display whether a corresponding button is selected or not, and for example, when the light-transmitting windows are configured on opposite corners of a single input button, a toggled state may be displayed as in a case where a button, i.e., [symbol] displays a toggle state between “LOCAL” or “REMOTE”.

Meanwhile, in an event of a user's request using the input buttons 40, etc., unlike normal times, the horizontal screen may display waveform information of a specific function and the vertical screen may display text information related to the same specific function. The horizontal screen is optimized for display of the waveform information, and the vertical screen is used for display of the text related to the displayed waveform information, thereby enabling efficient display of the information.

Under normal operation conditions, user's malfunction is maximally reduced by separating the meter screen and relay screen on two independent screens and displaying data on the set screens, separately. Further, when it is required to show a lot of graphic data, such as during waveform analysis or accident analysis, the convenience of use may be maximally increased by having a function for operating two screens in combination.

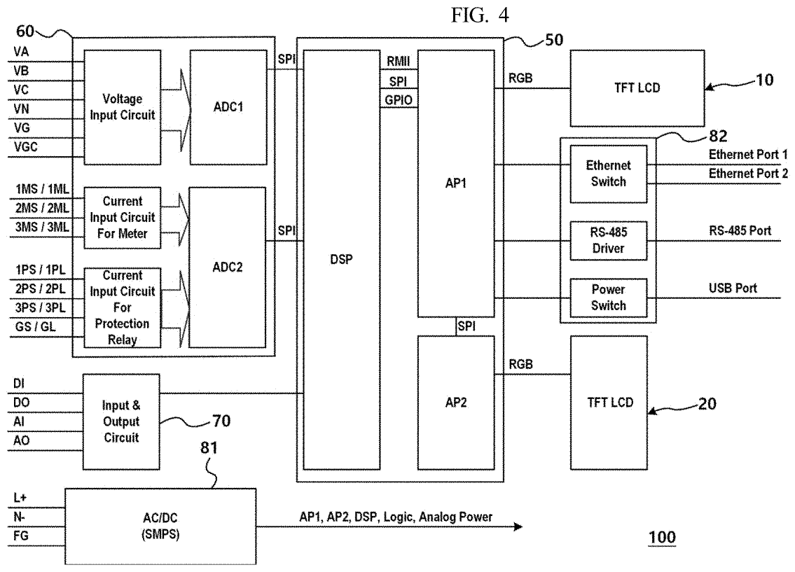

FIG. 4 is a schematical view illustrating electrical functional blocks of the electric device according to the exemplary embodiment of the present disclosure.

Content indicated inside each of blocks in the block diagram may indicate an exemplary embodiment of the corresponding blocks. The electric device 100 is configured to include: an electric signal input unit 60 configured to process real-time analog voltage signals and analog current signals, which are input by using system-mounted PT, CT, etc., and include a multi-channel analog-to-digital converter ADC1 and ADC2; a controller 50 configured to generate various meter function-related information by using real-time current signal data and voltage signal data, which are converted into digital signals by the electric signal input unit 60, and perform relay-related monitoring and control; a first display 10 and a second display 20, which are configured to display the information provided by the controller 50; a communication unit 82 configured to perform communication with an upper level system and/or a neighboring device; an input/output unit 70 configured to perform digital input/output and analog input/output, and provide and receive input/output signals to and from the controller 50; and a power supply unit 81 configured to supply power to the electric device.

The controller 50 may be configured to include: one high-performance DSP configured to perform various signal processing and calculation in a digital domain, and perform processing and control for performing a protection function as a relay; a first application processor AP1 configured to receive necessary information from the DSP to provide information (i.e., signals) to be displayed on the first display 10, and control a communication unit 82 to perform control and processing for performing a communication function; and a second application processor AP2 configured to receive necessary information from the first application processor AP1 to provide information (i.e., signals) to be displayed on the second display 20.

In particular, the content to be displayed on the first display 10 and the second display 20 may be toggled between each other depending on mounting directions of the electric device, and the controller 50 of the electric device, that is, specifically, the first application processor AP1, determines the mounting direction in which the electric device is mounted on the supporting body. The mounting direction is determined according to receiving of an input from the user (i.e., the manager) through the input buttons 40 provided in the electric device or respective touch screens configured in the first and second displays, or is determined by way of configuring a separate gravity sensor in the electric device, and sensing a gravity direction by using the configured gravity sensor.

In addition, the information displayed on the first display 10 and the second display 20 is determined differently according to the determined mounting direction. In normal times, when it is determined that the electric device is mounted on the supporting body in the horizontal direction, the first application processor AP1 may provide information related to the meter function to the first display 10 to display the information, and may transmit information related to the relay function to the second application processor AP2 so that the second application processor AP2 controls the second display 20 to display the information. When it is determined that the electric device is mounted on the supporting body in the vertical direction, the first application processor AP1 may provide the information related to the relay function to the first display 10 to display the information, and may transmit the information related to the meter function to the second application processor AP2 so that the second application processor AP2 controls the second display 20 to display the information. For convenience of description, the above description is described by assuming the shape of the electric device, the horizontal and vertical correspondence of the first display and the second display, and the correspondence of the first application processor and the second application processor, but it is natural that various forms are applicable.

Meanwhile, state information of the circuit breaker (not shown) configured in the system is input by using a DI terminal of the input/output unit 70, and a trip signal of the circuit breaker is output through a DO terminal. The controller 50, that is, specifically the DSP, monitors the real-time voltage signals and current signals through the electric signal input unit 60, and performs the relay function through a process such as providing the trip signal through the DO terminal when it is required to trip the circuit breaker.

1. An electric device mounted on a supporting body, the electric device comprising:
a first display (10) and a second display (20), which are configured in a same housing (30) and are facing a front,
wherein one of the first display (10) and the second display (20) provides a rectangular horizontal screen and displays information about a meter function, and
the other of the first display (10) and the second display (20) provides a rectangular vertical screen and displays information about a relay function.

2. An electric device mounted on a supporting body, the electric device comprising:
a first display (10) and a second display (20), which are configured in a same housing (30) and are facing a front,
wherein the first display (10) and the second display (20) are both rectangular and
a long side direction of the first display (10) and a long side direction of the second display (20) are orthogonal to each other, so that regardless of whether the electric device is mounted horizontally or vertically on the supporting body, one of the first display (10) and the second display (20) always provides a horizontal screen and the other of the first display (10) and the second display (20) always provides a vertical screen.

3. The electric device of claim 2, wherein, when the electric device is mounted on the supporting body in the horizontal direction, the first display (10) provides the horizontal screen and the second display (20) provides the vertical screen, and
when the electric device is mounted on the supporting body in the vertical direction, the first display (10) provides the vertical screen and the second display (20) provides the horizontal screen.

4. The electric device of claim 3, wherein the information displayed on the first display (10) when the electric device is mounted on the supporting body in the horizontal direction is displayed on the second display (20) when the electric device is changed to be mounted on the supporting body in the vertical direction, and
the information displayed on the second display (20) when the electric device is mounted on the supporting body in the horizontal direction is displayed on the first display (10) when the electric device is changed to be mounted on the supporting body in the vertical direction.

5. The electric device of claim 2, wherein, regardless of whether the electric device is mounted horizontally or vertically on the supporting body, in normal times, the horizontal screen fundamentally displays the information about the meter function, and
the vertical screen fundamentally displays the information about the relay function.

6. The electric device of claim 1, wherein the information about the meter function comprises waveform information, and
the information about the relay function comprises a distribution diagram and state information of a circuit breaker.

7. The electric device of claim 1, further comprising:
a plurality of input buttons (40) configured in the housing and facing the front,
wherein respective character strings displayed on the input buttons (40) are inclined toward a space between the first display (10) and the second display (20).

8. The electric device of claim 7, wherein, in some or all of the plurality of input buttons, light-transmitting windows (W) for LED lamps are provided on respective corner portions facing the space between the first display (10) and the second display (20).

9. The electric device of claim 2, further comprising:
a plurality of input buttons (40) configured in the housing (30) and facing the front,
wherein, at a user's request using the input buttons (40), the horizontal screen displays waveform information and the vertical screen displays text information.

10. A control method of an electric device mounted on a supporting body and provided with a first display (10) and a second display (20), which are configured in a same housing (30) and are facing a front, the control method comprising:
determining a mounting direction in which the electric device is mounted on the supporting body, wherein the first display (10) and the second display (20) are both rectangular, and a long side direction of the first display (10) and a long side direction of the second display are orthogonal to each other; and
determining information displayed on the first display (10) and the second display (20) to be different depending on the determined mounting direction.

11. The control method of claim 10, wherein the mounting direction is determined according to receiving of an input through input buttons or touch screens, which are provided in the electric device, or sensing of a gravity direction by using a sensor.

12. The electric device of claim 5, wherein the information about the meter function comprises waveform information, and
the information about the relay function comprises a distribution diagram and state information of a circuit breaker.

13. The electric device of claim 2, further comprising:
a plurality of input buttons (40) configured in the housing and facing the front,
wherein respective character strings displayed on the input buttons (40) are inclined toward a space between the first display (10) and the second display (20).

14. The electric device of claim 13, wherein, in some or all of the plurality of input buttons, light-transmitting windows (W) for LED lamps are provided on respective corner portions facing the space between the first display (10) and the second display (20).
